(19) United States
(12) Patent Application Publication
(10) Pub. No.: US 2024/0047416 A1
(43) Pub. Date: Feb. 8, 2024

(54) CHIP-TO-WAFER STACKING METHOD

(71) Applicant: WUHAN XINXIN SEMICONDUCTOR MANUFACTURING CO., LTD., Wubei (CN)

(72) Inventors: Tanlin CHEN, Wuhan (CN); Wanli GUO, Wuhan (CN); Tianjian LIU, Wuhan (CN)

(21) Appl. No.: 18/266,528

(22) PCT Filed: Dec. 21, 2020
(86) PCT No.: PCT/CN2020/138144

§ 371 Date: Jun. 9, 2023

(30) Foreign Application Priority Data
Dec. 10, 2020 (CN) 202011452333.X

(51) Int. Cl. H01L 23/00; H01L 21/683; H01L 21/768; H01L 21/78

(52) U.S. Cl. CPC H01L 24/94; H01L 24/83; H01L 21/6831; H01L 21/76898; H01L 21/78; H01L 2224/94; H01L 2224/83893

(57) ABSTRACT

A die-to-wafer stacking method includes: providing a wafer to be processed, including a substrate, a dielectric layer on the substrate and a metal layer embedded in the dielectric layer; forming a bonding layer covering the dielectric layer; picking up dies to be bonded from the wafer to be processed and arranging the dies to be bonded on an electrostatic chuck; and bonding the dies arranged on the electrostatic chuck, as a whole, to a wafer to be bonded. Pre-arranging all the dies to be bonded on the electrostatic chuck and then bonding the dies on the electrostatic chuck, as a whole, to the wafer to be bonded can greatly shorten post-activation waiting times of dies before they are bonded to the wafer and thus reduce the risk of loss of activation.

### TECHNICAL FIELD

The present invention pertains to the field of integrated circuit (IC) fabrication technology, and particularly relates to a die-to-wafer stack and a method of making it.

### BACKGROUND

As the microelectronics industry steps into the post-Moore's law era, chip structures are evolving toward three-dimensional (3D) stacking, which enables higher integration, greater miniaturization and more excellent performance. Compared with wafer-to-wafer (W2W) stacking, chip-to-wafer (C2W) heterogeneous integration is advantageous in allowing interconnection between dies of different technology nodes and different sizes with higher flexibility. Moreover, C2W integration allows known good dies (KGDs) to be chosen to be bonded to a wafer. This can result in a significantly increased yield. C2W integration has become an important area of development for 3D-IC technology.

At present, the mainstream technique for C2W integration in mass production applications is micro-bump packaging featuring a minimum interconnect size of 40 μm and the use of lower filler between bumps, which is, however, unfavorable to heat dissipation. The current research and development effort is being directed toward bumpless bonding, which features an even smaller interconnect size and direct copper-to-copper bonding achievable by hybrid bonding. It allows an interconnect size as small as 10 μm or less and hence higher input/output connection density, as well as better heat dissipation performance because it does not use lower filler.

However, bumpless bonding is also associated with some problems. Firstly, copper is easily oxidized. Secondly, in applications where a number of dies to be bonded are bonded to a wafer one by one after their hybrid bonding interfaces have been activated, some of them may have to wait for a long time during which their activation may be lost. Thirdly, it lacks efficiency in applications where dies of different sizes are densely bonded to a wafer region. These problems lead to great challenges to practical application of this technique in mass production.

### SUMMARY OF THE INVENTION

It is an objective of the present invention to provide a die-to-wafer stacking method, which can reduce the risk of an activated die losing its activation within a long waiting time before it is bonded to a wafer, resulting in higher die-to-wafer stacking efficiency.

The present invention provides a die-to-wafer stacking method, including:
providing a wafer to be processed, which includes a substrate, a dielectric layer on the substrate and a metal layer embedded in the dielectric layer, and forming a bonding layer covering the dielectric layer;
picking up dies to be bonded from the wafer to be processed and pre-arranging the dies to be bonded on an electrostatic chuck; and
bonding the dies pre-arranged on the electrostatic chuck, as a whole, to a wafer to be bonded.

Additionally, the method may further include, after the dies to be bonded are pre-arranged on the electrostatic chuck and before they are bonded to the wafer to be bonded,
subjecting a bonding surface of the wafer to be bonded and/or bonding surfaces of the arranged dies to plasma activation.

Additionally, the dies to be bonded may include dies of different functions and/or sizes.

Additionally, the dies to be bonded may be picked up from first wafer to be processed to N-th wafer to be processed, where N is an Integer ≥1, wherein first dies are picked up from the first wafer to be processed, i-th dies from the i-th wafer to be processed and N-th dies from the N-th wafer to be processed, where 1<i<N, and wherein the first, i-th and N-th dies are arranged into reconstructed dies on the electrostatic chuck, the reconstructed dies match respective dies on the wafer to be bonded.

Additionally, the reconstructed dies may be periodically arranged on the electrostatic chuck.

Additionally, the method may further include:
for each of the first wafers to be processed to N-th wafer to be processed, before the dies are picked up therefrom, coating a bonding surface of each wafer to be processed with a metal antioxidant after being diced; and
after the dies to be bonded are pre-arranged on the electrostatic chuck and before the dies are subjected to the plasma activation, the method further comprising: cleaning the dies to remove the metal antioxidant remaining on their bonding surfaces and subjecting the bonding surface to a hydrophilic treatment.

Additionally, a plurality of electrostatic chucks may be provided, wherein the dies are pre-arranged on the plurality of electrostatic chucks and then bonded to the wafer to be bonded.

Additionally, after the bonding layer is formed and before the dies to be bonded are picked up from the wafer to be processed, the method may further include:
bonding the bonding layer of the wafer to be processed towards a carrier wafer;
forming TSVs, which extend through the substrate and a partial thickness of the dielectric layer and expose the metal layer, and an interconnect layer in the TSVs, wherein the interconnect layer is electrically connected to the first metal layer;
attaching a blue tape or a UV tape to a surface of the wafer to be processed close with through openings of the TSVs;
debonding the carrier wafer and the wafer to be processed and removing the carrier wafer; and
dicing the wafer to be processed.

Additionally, the bonding layer of the wafer to be processed may be boned with the carrier wafer by a bonding adhesive, wherein
when the carrier wafer is debonded with the wafer to be processed and the carrier wafer is removed, the bonding adhesive may remain.

Additionally, picking up the dies to be bonded from the wafer to be processed includes: picking up the dies to be bonded from the blue tape or from the UV tape; and directly placing them on the electrostatic chuck.

Additionally, plasma used in the plasma activation may be produced from a gas including any one of oxygen, nitrogen, argon or hydrogen, or a combination of two or more thereof.

Additionally, the electrostatic chuck may be charged or discharged under the control of external commands, thereby retaining the arranged dies thereon by attraction or releasing them.

Additionally, the bonding of the pre-arranged dies on the electrostatic chuck as a whole with the wafer to be bonded may be accomplished using a method based on both thermal and mechanical loads, in which the mechanical load is applied to the dies on the electrostatic chuck, while the dies and the wafer are being heated in a vacuum environment, thereby forming atomic bonds between the bonding surface of the wafer to be bonded and the bonding surfaces of the arranged dies.

Compared with the prior art, the present invention provides the following benefits:
the present invention provides a die-to-wafer stacking method including: providing a wafer to be processed, which includes a substrate, a dielectric layer on the substrate and a metal layer embedded in the dielectric layer; forming a bonding layer covering the dielectric layer; picking up dies to be bonded from the wafer to be processed and arranging the dies to be bonded on an electrostatic chuck; and bonding the dies arranged on the electrostatic chuck, as a whole, to a wafer to be bonded. Pre-arranging all the dies to be bonded on the electrostatic chuck and then bonding the dies on the electrostatic chuck, as a whole, to the wafer to be bonded can greatly shorten post-activation waiting times of the dies before they are bonded to the wafer and thus reduce the risk of their loss of activation. Pre-arrangement of all the dies to be bonded on the electrostatic chuck followed by collective bonding of the dies on the electrostatic chuck is more efficient than simultaneous bonding and arrangement.

### BRIEF DESCRIPTION OF THE DRAWINGS

FIG. 1 depicts a flowchart of a die-to-wafer stacking method according to an embodiment of the present invention.

FIGS. 2, 3, 4a, 4b, and 5 to 14 are schematic illustrations of various steps in a die-to-wafer stacking method according to an embodiment of the present invention.

In these figures:

10—first wafer to be processed; 11—first substrate; 12—first dielectric layer; 13—first metal layer; 14—bonding layer; 15—insulating layer; 16—interconnect layer; 17—test pad layer; 18—test pad; 17′—hybrid bonding layer; 18′—metal pad; A—carrier wafer; B—blue tape; C—reconstructed die set; D₁—first die; D₂—second die; E—electrostatic chuck; W—wafer to be bonded; C′—bonded die.

### DETAILED DESCRIPTION

On the above basis, embodiments of the present invention provide a die-to-wafer stacking method. The present invention will be described in greater detail below with reference to the accompanying drawings and to specific embodiments. Advantages and features of the present invention will become more apparent from the following description. Note that the figures are provided in a very simplified form not necessarily drawn to exact scale and for the only purpose of facilitating easy and clear description of the embodiments.

Embodiments of the present invention provide a die-to-wafer stacking method, which, as shown in FIG. 1, includes:
step S1: providing a wafer to be processed, which includes a substrate, a dielectric layer on the substrate and a metal layer embedded in the dielectric layer, and forming a bonding layer covering the dielectric layer;
step S2: picking up dies to be bonded from the wafer to be processed and arranging the dies to be bonded on an electrostatic chuck; and
step S3: bonding the dies arranged on the electrostatic chuck, as a whole, to a wafer to be bonded.

The dies to be bonded may be identical dies, or dies of different functions and/or sizes.

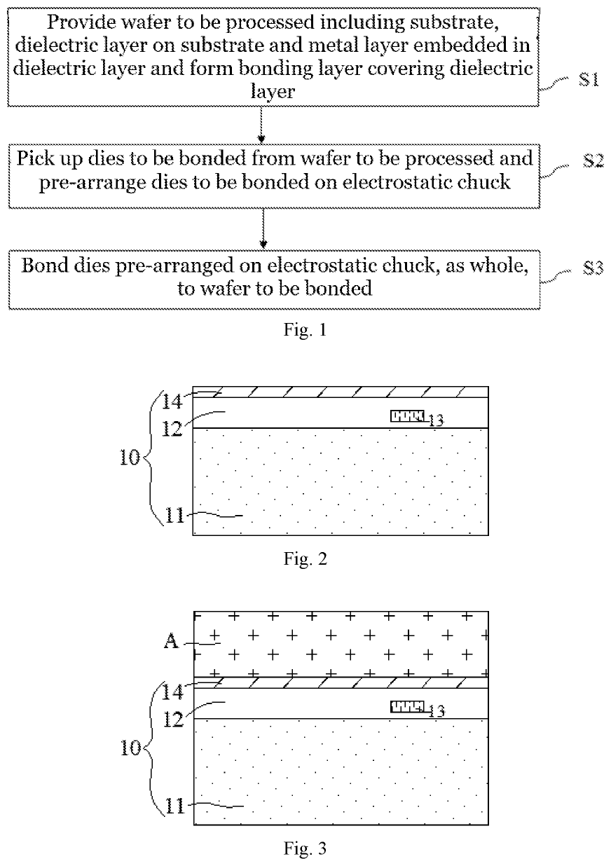

Various steps in a die-to-wafer stacking method according to an embodiment of the present invention will be described in detail below with reference to FIGS. 2, 3, 4a, 4b, and 5 to 14.

As shown in FIG. 2, a first wafer to be processed 10 is provided, the first wafer to be processed 10 includes a first substrate 11, a first dielectric layer 12 on the first substrate 11 and a first metal layer 13 embedded in the first dielectric layer 12. A bonding layer 14 is then formed, the bonding layer 14 covers the first dielectric layer 12. An upper surface of the bonding layer 14 may provide a bonding interface. Preferably, the bonding interface may be a hybrid bonding interface including both metal and insulating layers (not shown). As shown in FIG. 3, the first wafer to be processed 10 may be bonded at the bonding layer 14 to a carrier wafer A. The bonding may be temporary bonding accomplished with a bonding adhesive.

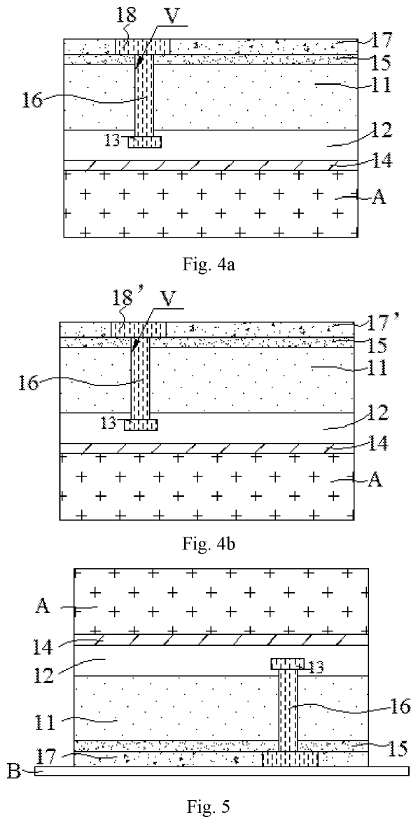

As shown in FIGS. 4a and 4b, the first wafer to be processed 10 is thinned. Specifically, the first substrate 11 may be thinned from the side away from the first metal layer 13. An insulating layer 15 is then formed on the thinned surface of the first substrate 11. Through-silicon vias (TSVs) V are formed, which extend through the insulating layer 15, the first substrate 11 and a partial thickness of the first dielectric layer 12 and expose the first metal layer 13. The first dielectric layer 12 is not limited to being formed as a single-layer dielectric layer. Instead, it may also be formed as a multi-layer composite, such as a composite dielectric layer including a silicon dioxide layer and a silicon nitride layer. An interconnect layer 16 is formed in the TSVs V. The interconnect layer 16 may be made of a metal such as copper or tungsten. In case of the interconnect layer 16 being implemented as a copper layer, it may be formed by electroplating. The interconnect layer 16 is electrically connected to the first metal layer 13. As shown in FIG. 4a, a test pad layer 17 is formed, the test pad layer 17 includes an insulating layer and test pads 18 embedded in the insulating layer. Through testing the first wafer to be processed 10 using the test pads 18, known good dies (KGDs) therein may be identified and marked. Preferably, a redistribution layer (not shown) may be inserted between the test pad layer 17 and the insulating layer 15. The redistribution layer may include a redistribution dielectric layer and a redistribution metal layer embedded in the redistribution dielectric layer. The redistribution metal layer may be electrically connected to the interconnect layer 16 so as to enable connection of electrical signals within the wafer. In an alternative embodiment, as shown in FIG. 4b, a hybrid bonding layer 17′ is formed, which includes an insulating layer and metal pads 18′ embedded in the insulating layer. Preferably, a redistribution layer (not shown) may be present between the hybrid bonding layer 17′ and the insulating layer 15.

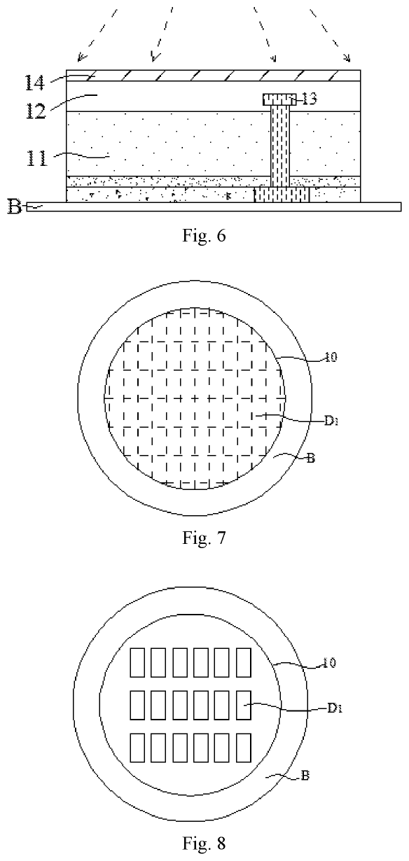

As shown in FIG. 5, a blue tape B is attached to a bask side of the first wafer to be processed 10. Preferably, the blue tape B is directly attached to the wafer to be processed without using a bonding adhesive. As shown in FIG. 6, the carrier wafer A is debonded from the first wafer to be processed 10, and the carrier wafer A is removed, preferably with the bonding adhesive being retained. As shown in FIGS. 6 and 7, the first wafer to be processed 10 is diced into individual first dies D₁, optionally by plasma cutting or laser cutting. The diced first wafer to be processed 10 is cleaned to remove the bonding adhesive and undesired particles produced during the cutting process. Removing the bonding adhesive after dicing enables the bonding adhesive to protect the bonding layer 14 from possible contamination during the previous processes. As the bonding layer 14 is temporarily bonded to the carrier wafer A immediately after being formed, it is away protected. This can result in enhanced bonding quality. Preferably, a metal antioxidant (e.g., a copper antioxidant) is sprayed onto a surface of the cleaned first wafer to be processed 10. In one embodiment, the copper antioxidant is a mixed solution composed of organic azoles, some additives and water. In another embodiment, the copper antioxidant includes a mixed solution composed of 1-hydroxyethylidene-1,1-diphosphonic acid, ethanol, hydrogen peroxide, benzotriazole, isothiocyanate, lauryl sulfate, sodium molybdate and sodium tripolyphosphate. The sprayed metal antioxidant can prevent or mitigate oxidation of the metal (e.g., copper) on the surface of the bonding layer 14 (hybrid bonding interface). This can exempt the dies from waiting times during their subsequent arrangement on an electrostatic chuck, thereby increasing flexibility in production scheduling.

As shown in FIGS. 8 to 10, dies to be bonded are arranged on an electrostatic chuck E. The dies to be bonded may be from a single wafer to be processed, or from different wafers to be processed. As an example, the dies to be bonded may from N wafers to be processed. That is, the dies to be bonded may be picked up from a first to N-th wafers to be processed, where N is a natural number ≥1. Specifically, first dies may be picked up from the first wafer to be processed, i-th dies from the i-th wafer (1<i<N) and N-th dies from the N-th wafer to be processed. The first, i-th and N-th dies are arranged and combined as reconstructed die sets on the electrostatic chuck. It would be appreciated that, when N=1, the dies to be bonded are picked up from a single wafer to be processed (a first wafer to be processed). When N=2, the dies to be bonded are picked up from a first wafer to be processed and a second wafer to be processed. When N≥3, the dies to be bonded are picked up from each i-th wafer to be processed. The terms “first”, “second” and “N-th” are used here only to distinguish one wafer or die from another wafer or die, without implying any particular order.

Preferably, after stripped from blue or UV tapes, the dies to be bonded are detached can be directly placed on the electrostatic chuck, without any baskside processing. This is because the electrostatic chuck can directly retain them thereon by attraction, without placing demanding bonding interface requirements. This can result in increased process simplicity.

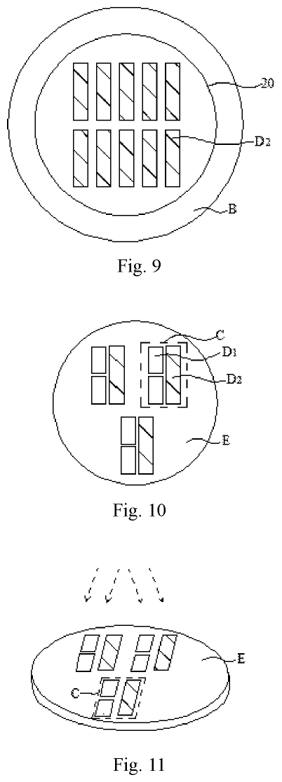

There is no limitation on the numbers of the first, i-th and N-th dies in each reconstructed die sets, and each of the numbers may be one or more (≥2). The reconstructed die sets match respective dies on the wafer to be bonded. The reconstructed die sets may be periodically distributed on the electrostatic chuck. As an example, continuing the example where N=2, as shown in FIG. 8, the first wafer to be processed 10 may be subjected to tape stretching (blue tape B), and first dies D₁ to be bonded may be picked up from the first wafer to be processed 10. As shown in FIG. 9, the second wafer to be processed 20 may be subjected to tape stretching (blue tape B), and the second dies D₂ to be bonded may be picked up from the second wafer to be processed 20. As shown in FIG. 10, the first D₁ and second D₂ dies may be arranged into reconstructed die sets C, which may be periodically distributed on the electrostatic chuck E.

The reconstructed die sets C may be retained (attracted) on the electrostatic chuck E through electrostatic attraction. In another embodiment, the reconstructed die sets C may alternatively be retained on (attached to) a substrate by an adhesive or adhesive foil (which may be designed to easily lose its adhesiveness when heated, irradiated with ultraviolet radiation or otherwise). In this way, the reconstructed die sets may be attached or detached (released) from the substrate, as desired.

In embodiments using an electrostatic chuck, the electrostatic chuck may be charged or discharged under the control of external commands to retain or release the dies. This is equivalent to the achievement of fast temporary bonding and debonding simply under the control of external signals, without using any additional process. This greatly shorten the waiting times of dies and hence the times for the copper to be oxidized. Preferably, loss of activation of the bonding interfaces can be avoided, resulting in increased process efficiency and improved bonding quality. It has not been proposed so far to collectively arrange and temporarily retain (bond) dies to be bonded on an electrostatic chuck and then bond them to a wafer.

As shown in FIG. 11, the reconstructed die sets C retained (attached) on the electrostatic chuck E are cleaned to remove the metal antioxidant remaining on their bonding interfaces and subjected to a hydrophilic treatment of the bonding interfaces.

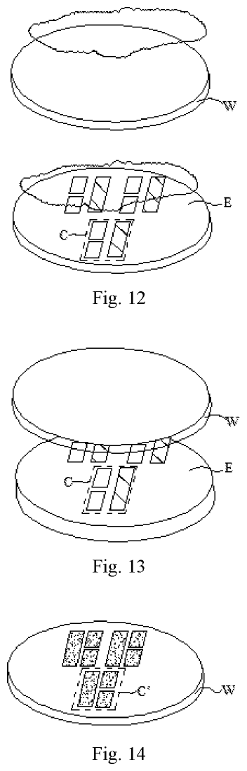

As shown in FIG. 12, bonding surfaces of the wafer to be bonded W and the arranged dies are activated with plasma. Plasma activation is a plasma-based surface modification method, which can modify the chemical and/or physical properties of a wafer surface by breaking bonds in silica molecules formed by natural or thermal oxidation thereon. Examples of a gas from which the plasma used in the plasma activation process can be produced may include, but are not limited to, oxygen (O₂) and inert gases such as nitrogen and/or argon. In one example, the plasma may be produced from oxygen. In another example, the plasma may be produced from nitrogen. The plasma may be produced from a gas mixture containing another suitable gas such as hydrogen. According to some embodiments, the gas from which the plasma is produced may present at a concentration of lower than 5%. In some embodiments, the plasma activation process may be conducted at a pressure between 0.05 mbar and 0.5 mbar and a discharge power level such as between 10 watts and 100 watts. In some embodiments, the plasma activation may be conducted a low-frequency discharge power level such as between 10 and 40 watts. In some embodiments, the plasma activation process may last for a period of time between 5 seconds and 50 seconds. In some embodiments, the plasma activation process may be conducted at a flow rate between 30 sccm and 80 sccm.

As shown in FIG. 13, the dies arranged on the electrostatic chuck E are bonded, as a whole, to the wafer to be bonded W. One or several (≥2) electrostatic chucks may be used, each retaining thereon one or several (≥2) reconstructed die sets. In case of several electrostatic chucks being used, they may retain thereon equal or different numbers of reconstructed die sets. FIG. 13 showing the bonding of dies arranged on one electrostatic chuck to the wafer to be bonded W. An area of the electrostatic chuck may be the same as or different from an area of the wafer to be bonded W. In other embodiments, dies arranged on several (≥2) electrostatic chucks may be bonded to the wafer to be bonded. That is, a single wafer to be bonded W may be aligned with and bonded to reconstructed die sets on one or more electrostatic chucks E. For example, the electrostatic chuck(s) E may have a smaller area than (or the same area as) the wafer to be bonded W. In case of several (≥2) the electrostatic chucks, reconstructed die sets may be separately arranged thereon as required and then bonded to the wafer to be bonded W. In this way, higher flexibility can be obtained in the arrangement of reconstructed die sets on the electrostatic chucks.

Die-to-wafer (C2W) bonding is intended to bond one or more known good dies (KGDs) to a wafer. In accordance with embodiments of the present invention, known good dies (KGDs) may be arranged into reconstructed die sets C as actually needed, which may be in turn distributed on an electrostatic chuck E into a repeated or non-repeated pattern as actually needed. As shown in FIGS. 13 and 14, all the dies arranged on the electrostatic chuck E may be directly pre-bonded, as a whole, to respective dies on a wafer to be bonded W and then released from the electrostatic chuck E, followed by withdrawal of the electrostatic chuck E. In this way, all the dies on the electrostatic chuck E can be transferred onto the respective dies on the wafer to be bonded W through pre-bonding. The reconstructed die sets C may be then bonded to the respective dies on the wafer to be bonded W, resulting in bonded dies C′. The bonded dies C′ may be subjected to surface cleaning and then annealed along with the wafer to be bonded W, thus achieving hybrid bonding.

The collective bonding of all the dies on the electrostatic chuck E to the respective dies on the wafer to be bonded W may be accomplished using a direct bonding method, such as a method based on both thermal and mechanical loads. In this method, a mechanical load may be applied to the multiple dies on the electrostatic chuck, while the dies and the wafer to be bonded may be being heated in a vacuum environment, in order to facilitate the formation of atomic bonds between their surfaces (typically metal surfaces, such as those of metal contact pads).

According to embodiments of the present invention, dies to be bonded are pre-arranged on an electrostatic chuck and collectively subjected to plasma activation of their bonding surfaces. Subsequently, all the dies on the electrostatic chuck are pre-bonded, as a whole, to a wafer to be bonded. This can greatly shorten waiting times of dies following the plasma activation and thus reduce the risk of loss of activation. According to embodiments of the present invention, pre-arrangement of the dies on the electrostatic chuck followed by bonding is more efficient than simultaneous bonding and arrangement.

The arrangement of the dies to be bonded on the electrostatic chuck may be designed as needed, and the designed pattern may be configured in the process parameters (recipe), thus achieving redistribution of effective dies (or dies of different sizes) on the electrostatic chuck. The range and positions of the dies should match those of the respective dies on the wafer to be bonded.

In summary, the present invention provides a die-to-wafer stacking method including: providing a wafer to be processed, which includes a substrate, a dielectric layer on the substrate and a metal layer embedded in the dielectric layer, and forming a bonding layer covering the dielectric layer; (S2) picking up dies to be bonded from the wafer to be processed and arranging the dies to be bonded on an electrostatic chuck; and bonding the dies arranged on the electrostatic chuck, as a whole, to a wafer to be bonded. Pre-arranging all the dies to be bonded on the electrostatic chuck and then bonding the dies on the electrostatic chuck, as a whole, to the wafer to be bonded can greatly shorten post-activation waiting times of dies and thus reduce the risk of loss of activation. Pre-arrangement of the dies on the electrostatic chuck followed by collective bonding of them is more efficient than simultaneous bonding and arrangement. Alternatively, the blue tape may be replaced with a UV tape, which can be simply stripped away from the dies when irradiated with UV radiation. The use of a UV tape can result in increased smoothness of the back side of the dies by reducing adhesive residuals thereon, which can facilitate the subsequent placement on the electrostatic chuck and bonding. Ultrathin dies (with a thickness <100 microns) can be more easily picked up from a UV tape.

The embodiments disclosed herein are described in a progressive manner with the description of each embodiment focusing on its differences from others, and reference can be made between the embodiments for their identical or similar parts. Since the method embodiments correspond to the device embodiments, they are described relatively briefly, and reference can be made to the device embodiments for details of the method embodiments.

The foregoing description presents merely preferred embodiments of the present invention and is not intended to limit the scope of the present invention in any way. Any and all changes and modifications made by those of ordinary skill in the art in light of the above teachings without departing from the spirit of the present invention are intended to be embraced in the scope as defined by the appended claims.

1. A die-to-wafer stacking method, comprising:
providing a wafer to be processed, which comprises a substrate, a dielectric layer on the substrate and a metal layer embedded in the dielectric layer, and forming a bonding layer, the bonding layer covering the dielectric layer;
picking up dies to be bonded from the wafer to be processed and pre-arranging the dies to be bonded on an electrostatic chuck; and
bonding the dies pre-arranged on the electrostatic chuck, as a whole, to a wafer to be bonded.

2. The die-to-wafer stacking method of claim 1, after the dies to be bonded are pre-arranged on the electrostatic chuck and before the dies are bonded to the wafer to be bonded, the method further comprising:
subjecting a bonding surface of the wafer to be bonded and/or bonding surfaces of the arranged dies to plasma activation.

3. The die-to-wafer stacking method of claim 1, wherein the dies to be bonded comprise dies of different functions and/or sizes.

4. The die-to-wafer stacking method of claim 1, wherein the dies to be bonded are picked up from first wafer to be processed to N-th wafer to be processed, where N is an Integer ≥1, wherein first dies are picked up from the first wafer to be processed, i-th dies from the i-th wafer to be processed and N-th dies from the N-th wafer to be processed, where 1<i<N, and wherein the first, i-th and N-th dies are arranged and combined to form reconstructed dies on the electrostatic chuck, the reconstructed dies match respective dies on the wafer to be bonded.

5. The die-to-wafer stacking method of claim 4, wherein the reconstructed dies are periodically arranged on the electrostatic chuck.

6. The die-to-wafer stacking method of claim 4, for each of the first wafers to be processed to N-th wafer to be processed, before the dies are picked up from a corresponding wafer to be processed, the method further comprising: coating a bonding surface of each wafer to be processed with a metal antioxidant after being diced.

7. The die-to-wafer stacking method of claim 1, wherein a plurality of electrostatic chucks are provided, wherein the dies are pre-arranged on the plurality of electrostatic chucks and then bonded to the wafer to be bonded.

8. The die-to-wafer stacking method of claim 1, after the bonding layer is formed and before the dies to be bonded are picked up from the wafer to be processed, the method further comprising:
bonding the bonding layer of the wafer to be processed towards a carrier wafer;
forming through-silicon vias (TSVs), which extend through the substrate and a partial thickness of the dielectric layer and expose the metal layer, and an interconnect layer in the TSVs, wherein the interconnect layer is electrically connected to the first metal layer;
attaching a blue tape or an ultraviolet (UV) tape to a surface of the wafer to be processed close with through openings of the TSVs;
debonding the carrier wafer and the wafer to be processed, and removing the carrier wafer; and
dicing the wafer to be processed.

9. The die-to-wafer stacking method of claim 8,
wherein the bonding layer of the wafer to be processed is boned with the carrier wafer by a bonding adhesive, and
wherein when the carrier wafer is debonded with the wafer to be processed and the carrier wafer is removed, the bonding adhesive remains.

10. The die-to-wafer stacking method of claim 8, wherein picking up the dies to be bonded from the wafer to be processed comprises: picking up the dies to be bonded from the blue tape or from the UV tape; and directly placing the dies to be bonded on the electrostatic chuck.

11. The die-to-wafer stacking method of claim 2, wherein plasma used in the plasma activation is produced from a gas comprising any one of oxygen, nitrogen, argon or hydrogen, or a combination of two or more thereof.

12. The die-to-wafer stacking method of claim 1, wherein the electrostatic chuck is charged or discharged under a control of external commands, thereby retaining the arranged dies thereon by attraction or releasing the arranged dies.

13. The die-to-wafer stacking method of claim 1, wherein the bonding of the pre-arranged dies on the electrostatic chuck as a whole with the wafer to be bonded is accomplished using a method based on both thermal and mechanical loads.

14. The die-to-wafer stacking method of claim 6, wherein after the dies to be bonded are pre-arranged on the electrostatic chuck and before the dies are subjected to the plasma activation, the method further comprising: cleaning the dies to remove the metal antioxidant remaining on the bonding surface.
